(19) United States
(12) Patent Application Publication
(10) Pub. No.: US 2025/0291265 A1
(43) Pub. Date: Sep. 18, 2025

(54) ALIGNMENT SYSTEM AND ALIGNMENT METHOD FOR SEMICONDUCTOR LITHOGRAPHY PROCESSES

(71) Applicant: LIDS SEMICONDUCTOR TECHNOLOGY CO., LTD., Taichung City (TW)

(72) Inventors: Chun-Jung Chiu, Taichung City (TW); Chun-Hsiung Chen, Taichung City (TW); Wen-Tung Yang, Taichung City (TW)

(21) Appl. No.: 19/078,475

(22) Filed: Mar. 13, 2025

(30) Foreign Application Priority Data
Mar. 15, 2024 (TW) 113109828

(51) Int. Cl. G03F 9/00; B65G 47/90; H01L 21/68

(52) U.S. Cl. CPC G03F 9/7049; B65G 47/90; G03F 9/7003; G03F 9/7076; H01L 21/681; H01L 21/682

(57) ABSTRACT

Disclosed is a three-stage alignment system and alignment method for semiconductor lithography, which significantly improves the accuracy of wafer alignment in semiconductor manufacturing. The alignment system includes a first alignment module for coarse alignment with a relatively large tolerance range; a second alignment module equipped with a dual-camera system for intermediate refinement of alignment based on wafer marks; and a third alignment module for fine alignment within a submicron tolerance range using mask marks on a photomask. A robotic arm transfers the wafer between stages, maintaining the integrity of the alignment. The wafer alignment marks are cross-shaped, while the photomask marks are square, thereby ensuring precise alignment in the third alignment module. This innovative method increases both the efficiency and accuracy of semiconductor device manufacturing.

### TECHNICAL FIELD

The present invention relates to the field of semiconductor manufacturing, particularly to the alignment process used in semiconductor lithography. More specifically, it pertains to a system and method for high-precision alignment of semiconductor wafers during a pattern transfer process.

### BACKGROUND

In semiconductor manufacturing, lithography is essential for transferring complex circuit patterns onto a semiconductor wafer. One critical aspect of this process is precise wafer alignment, which ensures that patterns can be accurately transferred across multiple lithographic steps. Conventionally, wafer alignment involves a two-step process: a coarse alignment stage followed by a fine alignment stage.

In the coarse alignment stage, the wafer is positioned so that a specific alignment mark is brought within a general proximity, often within a tolerance of about 50 micrometers. The fine alignment stage then refines the wafer position to within a tighter tolerance—often around 1 micrometer. One purpose of fine alignment is to align the wafer's region-to-be-imaged with the imaging field of the photomask in the lithography apparatus. However, fine alignment is constrained by the accuracy achieved in the coarse alignment. Often, mechanical limitations in the lithography equipment cause insufficient adjustments, leading to wafer misalignment beyond the system's capability, and thus the wafer alignment may fail.

As pattern feature sizes on wafers continue to shrink, increasingly precise alignment is needed. Accordingly, there is a demand for improvements in semiconductor lithography alignment systems—specifically, solutions bridging the accuracy gap between coarse and fine alignment, so as to enhance wafer positioning accuracy, increase alignment throughput, and reduce the probability of wafer alignment failure.

Therefore, how to improve the above problems is worth considering for those with ordinary knowledge in this field.

### SUMMARY

The present invention provides an advanced alignment system for semiconductor lithography that addresses the critical need for accurate wafer alignment in semiconductor manufacturing. Through a three-module alignment flow, the disclosed system improves wafer positioning accuracy and speed, reduces alignment failures, and significantly enhances the reliability and efficiency of the lithography process.

At the core of this invention is a series of alignment modules, each specialized for a particular stage of alignment. A first alignment module performs coarse alignment of the wafer. This first alignment module includes a first wafer chuck (a first carrier or “first support”) that positions the wafer within a relatively broad initial alignment tolerance range. In many implementations, the wafer is positioned within about 50 micrometers of the intended location, laying the groundwork for more precise alignment steps in subsequent modules.

Once coarse alignment is completed, the wafer proceeds to a second alignment module. Unlike the first module, the second module includes a second wafer chuck and a first dual-camera system. The second alignment module refines the wafer alignment to a narrower intermediate alignment tolerance range, based on two alignment marks on the wafer. The first dual-camera system of the second alignment module typically has a larger field of view than the second dual-camera system used in the final alignment stage, thereby “bridging the gap” between coarse alignment and highly precise fine alignment. This intermediate stage facilitates rapid and reliable final alignment, reducing the possibility of alignment failure when transitioning to the fine alignment.

The next phase of the alignment process takes place in a third alignment module. The third alignment module has a third wafer chuck and a second dual-camera system. The second dual-camera system is configured to align the wafer with mask marks on a photomask, such that the wafer can be aligned within a tighter tolerance—often about 1 micrometer or less—relative to the second module's intermediate tolerance. In one embodiment, the wafer alignment marks are cross-shaped, while the mask marks are square, allowing the third alignment module to complete precise alignment by detecting the cross-shaped wafer marks within the square mask marks in its smaller field of view.

Another feature of the disclosed alignment system is a robotic arm that transports the wafer between the first, second, and third alignment modules, while preserving the wafer's positional integrity. This mechanism ensures minimal disturbance or contamination during transfer, preserving both wafer integrity and alignment precision.

Furthermore, the invention includes a method for aligning wafers in semiconductor lithography, describing in detail the steps of coarse alignment in the first alignment module, mark-based alignment in the second alignment module, and fine alignment in the third alignment module.

In sum, the present invention constitutes a significant advancement in semiconductor manufacturing technology. By addressing the challenges of wafer alignment in lithography, the disclosed system and method provide a reliable, efficient, and highly accurate solution—crucial for meeting the stringent requirements of modern semiconductor devices.

### BRIEF DESCRIPTION OF THE DRAWINGS

The objects, spirits, and advantages of the preferred embodiments of the present disclosure will be readily understood by the accompanying drawings and detailed descriptions, wherein:

FIG. 1 is a schematic view illustrating a first embodiment of the wafer alignment system according to the present invention.

FIG. 2 is a flowchart illustrating a first embodiment of the wafer alignment method of the present invention.

FIG. 3A is a partial schematic view of the wafer alignment system disclosed by the present invention.

FIG. 3B is a schematic view of the carrier chuck and sensor of the wafer alignment system.

FIG. 4 is a top schematic view of a wafer, illustrating mark alignment.

FIG. 5 is a top schematic view of the photomask and wafer, illustrating fine alignment.

FIG. 6 is a schematic view of the robotic arm employed by the wafer alignment system.

FIG. 7 is a schematic view illustrating a second embodiment of the wafer alignment system according to the present invention.

### DETAILED DESCRIPTION

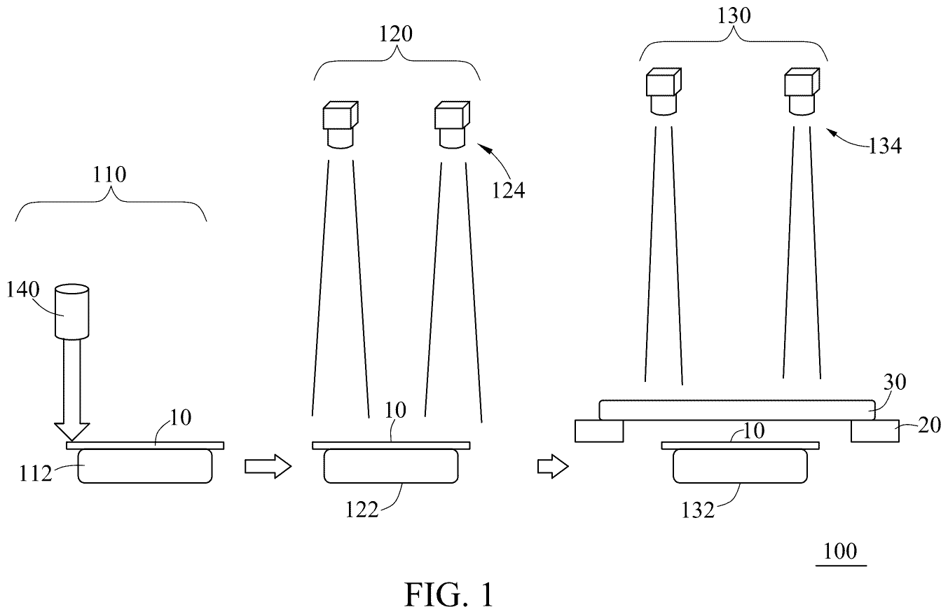

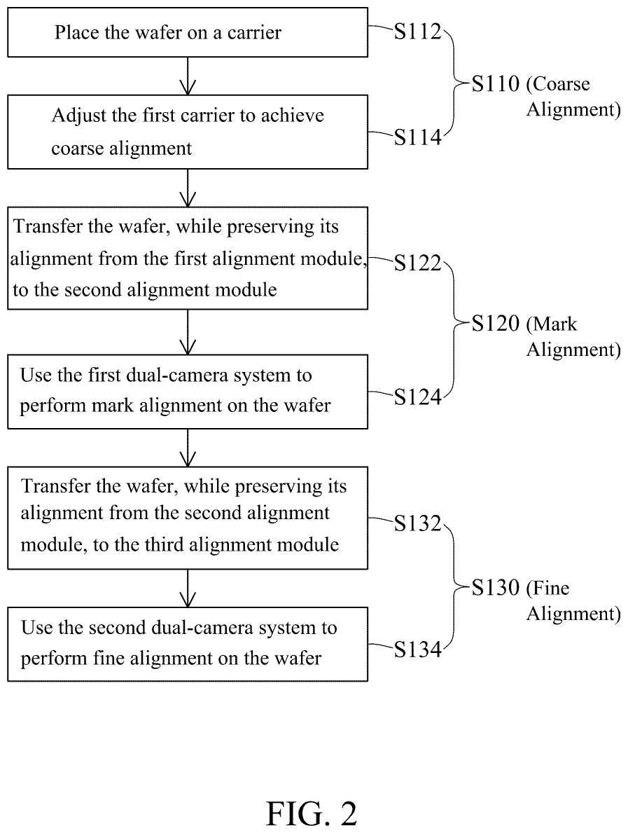

Referring simultaneously to FIG. 1 and FIG. 2, FIG. 1 illustrates a first embodiment of an alignment system 100 for semiconductor lithography according to the present invention, and FIG. 2 is a flowchart illustrating a first embodiment of the wafer alignment method of the present invention. In this embodiment, the alignment system 100 includes a first alignment module 110, a second alignment module 120, and a third alignment module 130. The first alignment module 110 includes a first carrier 112 for supporting a wafer 10 and a sensor 140. The second alignment module 120 includes a second carrier 122 for supporting the wafer 10 and a first dual-camera system 124. The third alignment module 130 includes a third carrier 132 for supporting the wafer 10, a second dual-camera system 134, and a photomask carrier for holding a photomask 30.

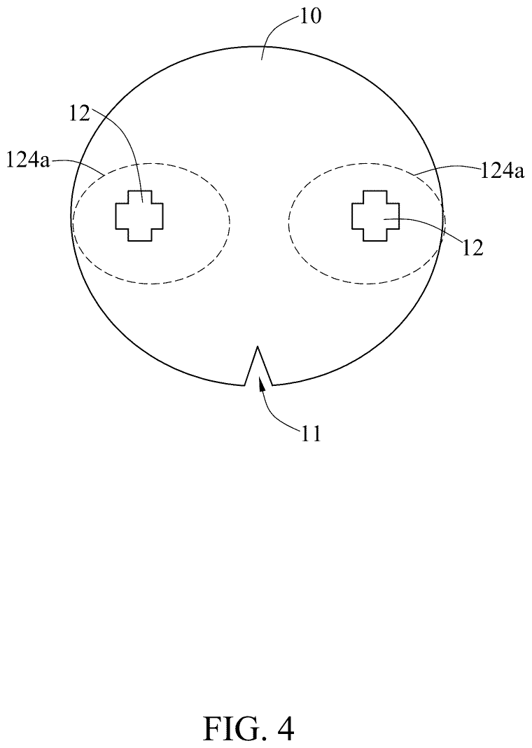

The relative positions among the first alignment module 110, the second alignment module 120, and the third alignment module 130 are pre-calibrated and set to be consistent. In other words, the positions of the first dual-camera system 124, the second dual-camera system 134, and the wafer alignment marks 12 on the wafer 10 in the first alignment module 110 (see FIG. 4) are correspondingly matched. Each of the first carrier 112, the second carrier 122, and the third carrier 132 is equipped with actuators that allow rotation and multi-axis (X and Y axes) horizontal motion so that the wafer 10 can be properly aligned. In particular, the first alignment module 110 is responsible for performing the coarse alignment S110 of the wafer 10, the second alignment module 120 is responsible for mark alignment S120, and the third alignment module 130 is responsible for fine alignment S130. As will be described later, a wafer transfer device is employed to maintain the correspondingly aligned position while moving the wafer 10 into or out of the first carrier 112, the second carrier 122, or the third carrier 132.

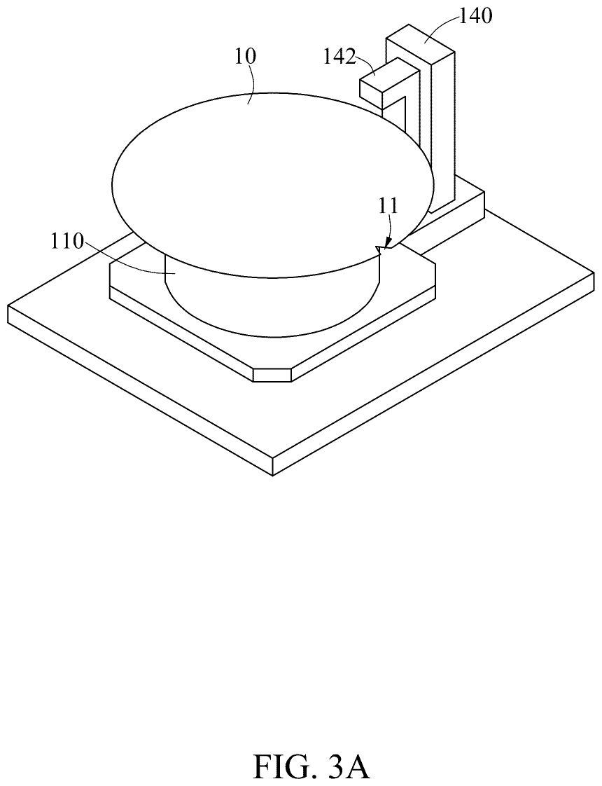

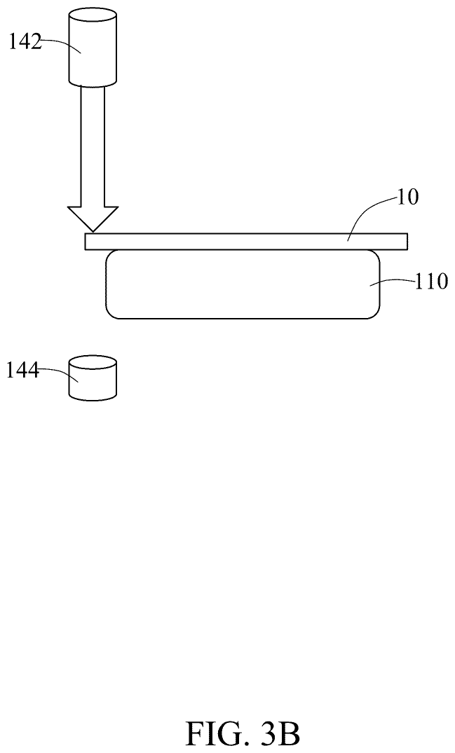

The first alignment module 110 is responsible for coarse alignment S110 of the wafer 10. The first alignment module 110 includes a robust and precisely built first carrier 112, which supports the wafer 10. When carrying out the alignment method of this invention, one first performs step S110, i.e., the initial coarse alignment S110 using the first alignment module 110. At the coarse alignment S110 stage (see step S112), the wafer 10 is placed onto the first carrier 112 by the transfer equipment. Next, step S114 is performed: the first carrier 112 undergoes a series of controlled movements—including rotation and X/Y axis motion along multiple horizontal axes—to adjust the position of the wafer 10 and achieve the coarse alignment S110. The coarse alignment S110 implemented by the first alignment module 110 lays the groundwork for subsequent alignment stages. In this coarse alignment S110 stage, a particular mark 11 (see FIG. 3A) on the wafer 10 is moved to a predetermined position zone in preparation for finer mark alignment S120 in the subsequent modules. In one embodiment, the wafer is positioned within a relatively broad tolerance of about 50 micrometers. In this embodiment, the particular mark 11 on the wafer 10 is present from the time the wafer 10 is manufactured; it serves as a reference point for positioning in subsequent processes.

Referring also to FIG. 3A and FIG. 3B, FIG. 3A illustrates the first alignment module 110 disclosed in the present invention, and FIG. 3B shows a schematic diagram of the first carrier 112 and sensor 140 in the first alignment module 110. The first alignment module 110 in the alignment system 100 is specifically designed to perform the coarse alignment S110, which is the initial step of the overall alignment process. The first carrier 112 of the first alignment module 110 is a precision platform for supporting and positioning the wafer 10. Once the wafer 10 is placed on the first carrier 112, edge detection of the wafer 10 is performed, and the wafer 10 undergoes multi-axis horizontal adjustments (i.e., X axis, Y axis, and rotation). The first carrier 112 is equipped with multiple actuators (not shown) that enable the wafer 10's coarse alignment S110. These actuators can move and rotate the first carrier 112 along various axes, thereby moving the wafer 10 to an initial adjustment position required for the subsequent modules.

During the coarse alignment S110 for the particular mark 11, the sensor 140 in the first alignment module 110 plays a critical role in aligning the particular mark 11 on the wafer 10. The optical sensor 140 comprises several key components that facilitate high-resolution and sensitive scanning. These components include a light source 142—commonly a laser or LED—for illuminating the wafer 10's edge. A photodetector 144, typically a photodiode or a CCD (charge-coupled device), collects the reflected or scattered light, converting incoming light into electrical signals. The sensor 140 also includes a lens assembly (not shown) to focus the light onto the photodetector. The sensor 140 is designed with high sensitivity and resolution so that even in the presence of microscopic variations or contamination near the wafer 10's edge, it can reliably detect both the particular mark 11 and unique features of the wafer's edge.

When aligning the particular mark 11, the first carrier 112 moves the wafer 10 in the X and Y directions and rotates it until this particular mark 11 aligns with a predefined location. The movement and rotation of the first carrier 112 employ high-precision motors controlled by advanced algorithms that consider factors such as inertia, mechanical resistance, and even microscopic debris that might interfere with motion. The movement speed and torque are carefully calibrated to ensure that the wafer 10 comes to rest precisely at the required predetermined location.

Referring to FIGS. 1, 2, and 4, the wafer 10 includes alignment marks 12 whose positions are set to correspond to the first field of view 124a of the first dual-camera system 124 in the second alignment module 120; the distance between these alignment marks 12 and the particular mark 11 is preset. (The formation of the wafer marks 12 will be explained later in this specification.) The predetermined position to which the wafer 10 is set in the first alignment module 110 is not chosen arbitrarily; instead, it corresponds to what is needed at the next stage (the mark alignment S120). More specifically, the wafer 10's alignment marks 12 are moved on the first carrier 112 to a position within the first field of view 124a of the first dual-camera system 124. Once the wafer 10 is correctly positioned, it is locked into place, typically through vacuum suction or a mechanical clamp that prevents unintended movement.

In this embodiment, the first alignment module 110 positions the wafer 10 within a tolerance of about 50 micrometers. Although this precision is insufficient for the complex requirements of pattern transfer in lithography, it does place the wafer 10—based on the particular mark 11—within the necessary alignment range for the first field of view 124a of the first dual-camera system 124 in the second alignment module 120. In the present embodiment, the particular mark 11 is a notch, but it could also be a flat edge formed along the wafer's curved boundary. Moreover, in this embodiment, the diameter of the first carrier 112 is smaller than the diameter of the wafer 10, allowing the light emitted by the light source 142 to pass to the photodetector 144.

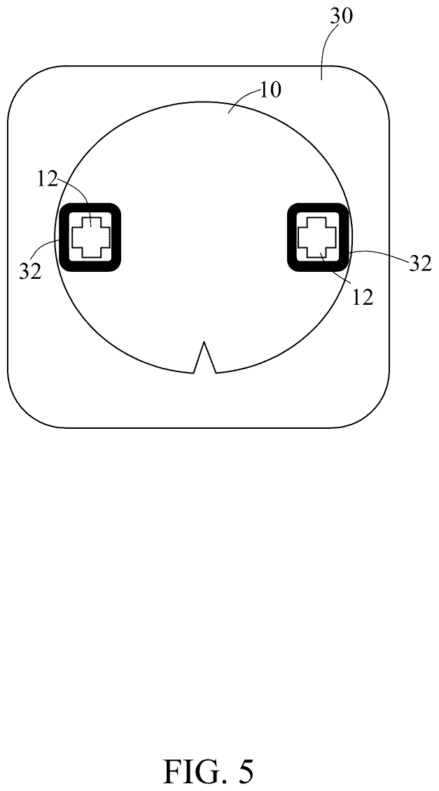

After completion of the coarse alignment S110, step S120 is carried out, namely the mark alignment S120 stage. In this stage, the second alignment module 120 performs an intermediate refinement of the tolerance range. The second alignment module 120 includes a second carrier 122 for supporting the wafer 10 and a first dual-camera system 124. At this stage, as shown in step S122, the wafer 10 is transferred—according to its position after the coarse alignment S110—to the second carrier 122 of the second alignment module 120. In this embodiment, the second carrier 122 of the second alignment module 120 is similar in design to the first carrier 112. However, in other embodiments, the second carrier 122 does not necessarily have to be smaller in diameter than the wafer 10. The first dual-camera system 124 of the second alignment module 120 is positioned to correspond to the location of the alignment marks 12. The first field of view 124a of this first dual-camera system 124 is larger than the second field of view 134a of the second dual-camera system 134 in the third alignment module 130. At this stage, the larger field of view allows the cameras of the first dual-camera system 124 to more easily capture and process the alignment marks 12 on the wafer 10, bringing them within the next stage's fine alignment S130 and into the second field of view 134a of the second dual-camera system 134, where the wafer marks 12 and photomask marks 32 (see FIG. 5) will be aligned. In one embodiment, each camera of the first dual-camera system 124 can simultaneously capture one of the two alignment marks 12 on the wafer 10—that is, each camera corresponds to one of the alignment marks 12.

During the mark alignment stage (step S120), the wafer 10 undergoes a refinement process that narrows the alignment tolerance range. As shown in step S124, the first dual-camera system 124 aligns the wafer 10 based on two alignment marks 12. The positions of these alignment marks 12 on the wafer 10 have been designed such that, during the previously mentioned coarse alignment S110, they are moved into the first field of view 124a of the cameras in the first dual-camera system 124 for detection and alignment. The second alignment module 120 uses these two alignment marks 12 to adjust the wafer 10, ensuring it is aligned within a second alignment tolerance range that is narrower than the first alignment tolerance range. In this embodiment, the second alignment tolerance range means positioning the alignment marks 12 so that they fall within the second field of view 134a of the second dual-camera system 134.

This refinement process in the mark alignment S120 stage aims to reduce the alignment error to a manageable range for the second dual-camera system 134 in the next fine alignment S130 stage. During mark alignment S120, the cameras of the first dual-camera system 124 work in conjunction with advanced image-processing algorithms to locate the alignment marks 12 precisely and compute the necessary positional adjustments for the wafer 10. This process involves a combination of X, Y, and rotational movement, finely tuning the position of the wafer's alignment marks 12 so that they will lie within the second field of view 134a of the second dual-camera system 134 of the third alignment module 130 in the next fine alignment S130 stage.

Next, step S130 is carried out in the third alignment module 130, which performs the fine alignment S130. The third alignment module 130 is equipped with a third carrier 132 and a second dual-camera system 134. The second dual-camera system 134 is correspondingly positioned to match the location of the alignment marks 12 on wafer 10 observed by the first dual-camera system 124, and it possesses higher precision and more advanced optical capabilities, as well as a smaller second field of view 134a compared to the first dual-camera system 124. Within the third alignment module 130, a photomask carrier 20 is provided to hold the photomask 30. The photomask 30 has mask marks 32, which are preset to correspond to the second field of view 134a of the second dual-camera system 134.

At this stage (step S132), the wafer 10—aligned in the preceding mark alignment S120 stage—is transferred to the third carrier 132. Subsequently, step S134 is executed: the cameras of the second dual-camera system 134 check whether the mask marks 32 (see FIG. 5) on the photomask 30 supported by the photomask carrier 20 correspond to the wafer alignment marks 12 on the wafer 10. The wafer 10 on the third carrier 132 is then adjusted in the X, Y, and rotational axes so that the wafer's alignment marks 12 align with the mask marks 32 on the photomask 30. These square-shaped marks 32 on the photomask correspond to the cross-shaped alignment marks 12 on the wafer 10. During this stage, the second dual-camera system 134, with its high-resolution optics and concentrated field of view, is crucial. It precisely aligns the wafer's alignment marks 12 to within the photomask's permissible alignment tolerance, typically about 1 micrometer or less, ensuring the cross-shaped alignment marks 12 on the wafer 10 are located within the square-shaped mask marks 32 on the photomask 30. The fine alignment S130 stage is extremely important for accurately transferring the pattern from the photomask 30 to the wafer 10 in the subsequent lithography process.

It should be noted that the third carrier 132 of the third alignment module 130 is specifically designed for the high-precision positioning required by the fine alignment S130. The third carrier 132 is equipped with multiple high-precision actuators capable of performing very small and controlled movements in multiple axes—movements that are crucial for the fine adjustments required in the fine alignment process. Furthermore, in addition to horizontal X, Y, and rotational motions, the third carrier 132 can also move vertically (i.e., along the Z-axis), permitting direct lithographic exposure on the third carrier once the alignment is complete. In addition, the second dual-camera system 134 of the third alignment module 130 differs from the first dual-camera system 124 of the second alignment module 120. The second dual-camera system 134 features a higher-resolution optical arrangement specifically designed to detect with extreme precision the alignment marks 12 on the wafer 10 and the mask marks 32 on the photomask. Compared to the first dual-camera system 124, the cameras in the second dual-camera system 134 have a smaller, more focused second field of view 134a, meeting the higher accuracy requirements of this alignment stage.

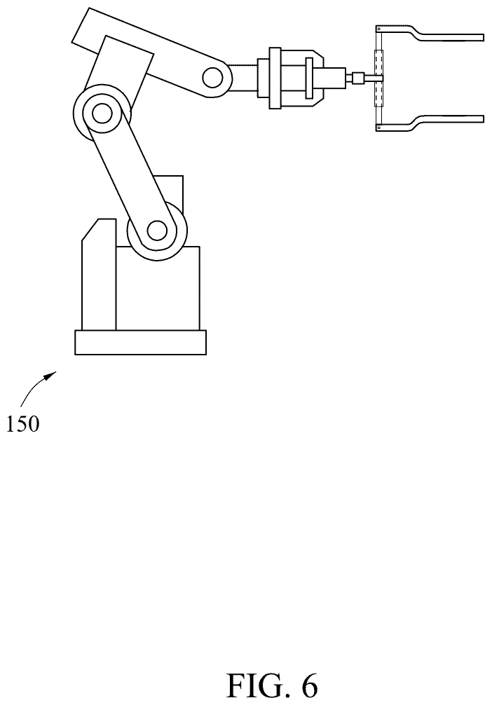

Referring also to FIG. 6, which is a schematic diagram showing a robotic arm 150 as the wafer-transfer device in the present invention, the alignment system 100 further includes the robotic arm 150 (FIG. 6) for transferring the wafer 10 among the first carrier 112, the second carrier 122, and the third carrier 132. Because the relative positions among the first carrier 112, the second carrier 122, and the third carrier 132 have been pre-measured and set, the robotic arm 150 can maintain the position the wafer 10 achieved in each prior stage during transport, ensuring that the alignment adjustments made in one stage are not disturbed in the next stage.

The robotic arm 150 is designed to handle the wafer 10 with very high precision and care, using materials compatible with the cleanroom environment of semiconductor manufacturing. The design of the robotic arm 150 emphasizes smooth and controlled movement to avoid disturbances that could affect wafer 10 alignment or introduce particle contamination. The robotic arm 150 is equipped with multiple sensors and actuators (not shown) to perform precise motion. These sensors provide real-time feedback on the position of the robotic arm 150 and the orientation of the wafer 10, ensuring accurate placement of the wafer 10 at each stage. The actuators in the robotic arm 150 are designed for smooth yet precise operation, allowing the robotic arm 150 to maintain the wafer's relative position while transferring it among the alignment modules.

In summary, the robotic arm 150 works in close coordination with the first alignment module 110, the second alignment module 120, and the third alignment module 130. After each alignment module completes its respective alignment, the robotic arm 150 gently lifts the wafer, transferring it precisely to the next alignment module or a designated storage location.

In the above-described embodiment, the alignment marks 12 on the wafer 10 are cross-shaped, while the photomask marks 32 on the photomask 30 are square-shaped. The wafer alignment marks 12 are designed as crosses because their geometry facilitates highly accurate detection and alignment by the first dual-camera system 124 and the second dual-camera system 134. The intersecting lines of the cross provide a clear reference that can be consistently identified by image-processing algorithms. The square-shaped mask marks 32 on the photomask 30 correspond to the position and size of the cross-shaped wafer alignment marks 12. When the wafer 10 is correctly aligned, these square marks 32 enclose the cross alignment marks 12 on the wafer 10. The square boundaries of the mask marks 32 are easily detected by the second dual-camera system 134, thereby achieving the fine alignment S130.

It should be noted that the cross-shaped wafer alignment marks 12 on the wafer 10 and the square-shaped photomask marks 32 on the photomask 30 in this disclosure represent only one embodiment; other shapes may be substituted. For example, the photomask 30 could have circular ring-shaped mask marks 32, while the wafer 10 might use circular dot marks for its alignment marks 12. Other easily detectable shapes for alignment are also feasible.

Furthermore, the formation of the wafer alignment marks 12 occurs at an early initial stage of semiconductor manufacturing. The positions of the wafer alignment marks 12 are predetermined to correspond to the positions of the first dual-camera system 124 and the second dual-camera system 134, as well as to have a defined distance from the particular mark 11 on the wafer 10. This design ensures that one can adjust the wafer from the particular mark 11 to the positions corresponding to the first dual-camera system 124 and the second dual-camera system 134. Typically, the alignment marks 12 are formed during the first lithography process, at which point there are not yet any circuit patterns requiring alignment on the wafer 10. The lithography process requires only the coarse alignment S110 in the first alignment module 110, wherein the particular mark 11 on the wafer 10 is used to position the wafer at a preset distance relative to the alignment marks 12. After that positioning is completed, one can proceed to form the wafer alignment marks 12 by lithography. In addition to lithographic etching, high-precision imprinting or laser stripping may also be used to create these alignment marks 12 on the wafer surface, ensuring that they can be easily identified and accurately aligned in the first alignment module 110, the second alignment module 120, and the third alignment module 130.

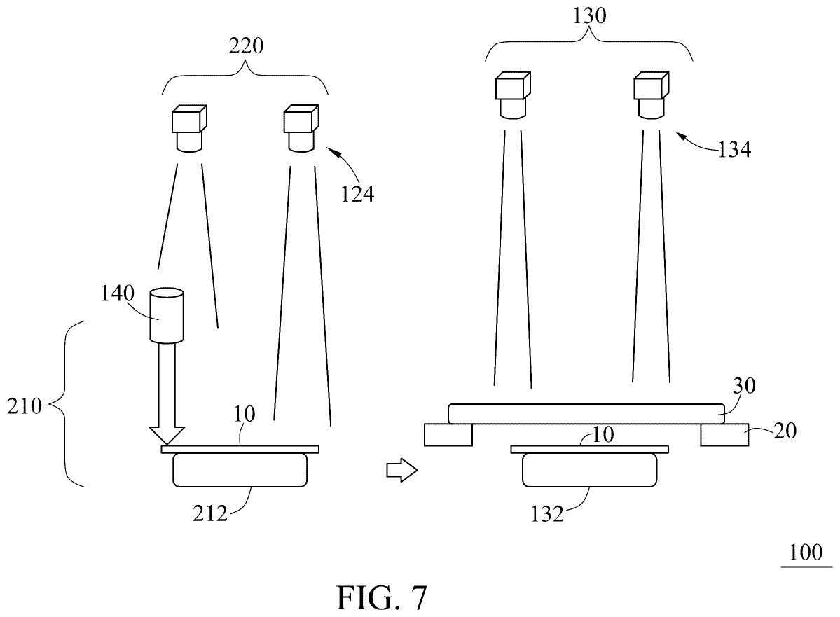

Next, referring to FIG. 7, FIG. 7 shows a schematic diagram of a second embodiment of the wafer alignment system 200 according to the present invention. In this embodiment, the first alignment module 210 and the second alignment module 220 in the wafer alignment system 200 share the same carrier 212. This shared-carrier design simplifies the alignment process and allows continuous operation between these two stages without having to transfer the wafer 10 from one carrier to another.

Using this shared carrier 212, the first alignment module 210 performs the initial coarse alignment S110. The wafer 10 is placed on the carrier, and the coarse alignment S110 is executed, positioning the wafer 10 within about 50 micrometers of the first alignment tolerance range by means of the sensor 140 (see FIG. 3A). After completing the coarse alignment S110, the wafer 10 need not be transferred to a different carrier for performing the mark alignment S120. An important feature of this embodiment is that the first dual-camera system 124 is placed directly above the shared carrier 212. Once the coarse alignment is finished, the same carrier 212 is immediately used to carry out the mark alignment S120, without moving the wafer 10. The first dual-camera system 124, located overhead, is activated to detect and refine the wafer 10's alignment further based on the two alignment marks 12 on the wafer 10 surface (see FIG. 4). This configuration improves the efficiency of the alignment process by reducing the time and complexity associated with wafer handling between the coarse alignment S110 and the mark alignment S120 stages.

Although the present disclosure has been disclosed and illustrated with reference to particular embodiments, the principles involved are susceptible for use in numerous other embodiments that will be apparent to a person having ordinary skill in the art. This disclosure is, therefore, to be limited only as indicated by the scope of the appended claims.

What is claimed is:

1. An alignment system for semiconductor lithography, comprising:
a first alignment module including a first carrier configured to support a wafer, the first carrier being movable to perform coarse alignment of said wafer based on a particular mark on the wafer such that the wafer is brought within a first alignment tolerance;
a second alignment module including a second carrier and a first dual-camera system, the second carrier being configured to support and move the wafer, and the first dual-camera system being arranged to further refine movement of the wafer to a narrower second alignment tolerance, based on two alignment marks on the wafer, wherein the second alignment tolerance is tighter than the first alignment tolerance; and
a third alignment module including a third carrier, a second dual-camera system, and a photomask carrier, the third carrier being configured to support and move the wafer, the photomask carrier being configured to carry a photomask, and the second dual-camera system being configured to align the wafer within a third alignment tolerance, which is tighter than the second alignment tolerance, based on two alignment marks on the wafer corresponding to two mask marks on the photomask;
wherein a first field of view of the first dual-camera system is greater than a second field of view of the second dual-camera system, so that after alignment in the second alignment module, the wafer's two alignment marks fall within the second field of view of the second dual-camera system for fine alignment.

2. The alignment system of claim 1, wherein the first alignment module is configured to position the wafer within about 50 micrometers of tolerance.

3. The alignment system of claim 1, wherein the third alignment module is configured to align the wafer to about 1 micrometer or less of tolerance.

4. The alignment system of claim 1, further comprising a robotic arm configured to transfer the wafer among the first carrier, the second carrier, and the third carrier.

5. The alignment system of claim 1, wherein the first carrier and the second carrier are the same carrier.

6. The alignment system of claim 1, wherein the alignment marks on the wafer are cross-shaped, and the mask marks on the photomask are square-shaped, and the third alignment module is configured to complete alignment within the third alignment tolerance when the second dual-camera system observes that the cross-shaped wafer marks are positioned within the square-shaped mask marks.

7. The alignment system of claim 1, wherein the first dual-camera system is configured to simultaneously capture images of the two alignment marks on the wafer.

8. A method for wafer alignment in semiconductor lithography, comprising:
performing a coarse alignment within a first alignment tolerance using a first alignment module having a first carrier supporting the wafer;
performing an intermediate mark alignment within a second, tighter alignment tolerance using a second alignment module having a second carrier and a first dual-camera system, wherein the alignment is based on two alignment marks on the wafer; and
performing a fine alignment within a third, tighter alignment tolerance using a third alignment module having a third carrier and a second dual-camera system, wherein the fine alignment is based on two mask marks on a photomask corresponding to the wafer's two alignment marks;
wherein the first dual-camera system has a first field of view larger than a second field of view of the second dual-camera system, ensuring that after alignment in the second alignment module, the wafer's two alignment marks lie within the second field of view of the second dual-camera system for fine alignment.

9. The method of claim 8, wherein positioning the wafer with the first alignment module places it within about 50 micrometers of tolerance.

10. The method of claim 8, wherein positioning the wafer with the third alignment module places it within about 1 micrometer or less of tolerance.

11. The method of claim 8, further comprising transferring the wafer among the first carrier, the second carrier, and the third carrier using a robotic arm.

12. The method of claim 8, wherein the first carrier and the second carrier are the same carrier.

13. The method of claim 8, wherein during alignment in the third alignment module, the wafer's cross-shaped alignment marks are positioned within the photomask's square-shaped mask marks, thereby completing alignment within the third alignment tolerance.

14. The method of claim 8, wherein the first dual-camera system is configured to simultaneously capture images of the two alignment marks on the wafer.
